(19) United States
(12) Patent Application Publication
(10) Pub. No.: US 2025/0087457 A1
(43) Pub. Date: Mar. 13, 2025

(54) INVERTED PLASMA SOURCE, AND METHOD

(71) Applicant: MKS Instruments, Inc., Andover, MA (US)

(72) Inventors: Gordon HILL, Andover, MA (US); Ron COLLINS, Andover, MA (US)

(73) Assignee: MKS Instruments, Inc., Andover, MA (US)

(21) Appl. No.: 18/825,455

(22) Filed: Sep. 5, 2024

Related U.S. Application Data
(60) Provisional application No. 63/581,292, filed on Sep. 8, 2023.

(51) Int. Cl. H01J 37/32

(52) U.S. Cl. CPC H01J 37/32091; H01J 37/32853; H01J 2201/306; H01J 2217/49257

(57) ABSTRACT

A plasma source is configured to be in fluid communication with the interior of a vacuum vessel, a vacuum chamber, such as by being installed in a wall of a vacuum vessel that encloses the chamber, or in a pipe that is connected to the chamber. The plasma source may produce plasma in a line of sight of a surface to be cleaned, such as an internal surface of the vessel, which may be used for processes such as deposition or etching.

### RELATED APPLICATIONS

This application claims the benefit under 35 USC 119(e) of U.S. Provisional Application 63/581,292, filed Sep. 8, 2023, which is incorporated by reference in its entirety. U.S. application Ser. No. 18/631,119, filed Apr. 10, 2024, is also incorporated by reference in its entirety.

### FIELD

The disclosure is in the field of plasma sources, and methods for using plasma sources to clean vacuum vessels.

### BACKGROUND

A compact inverted toroidal plasma source offers the advantage of generating reactive radicals at the point of use of a region of a vacuum system that is to be cleaned. The vacuum system is often a semiconductor deposition or etch chamber, or a vacuum pumping line downstream of the chamber. However, such a plasma source must be integrated into the vacuum system, or chamber, ideally with minimal disruption to the intended function of that chamber. It can be desirable to have controlled flow patterns with a semiconductor etch or deposition chamber. These flow patterns are usually desired to be axisymmetric around the wafer pedestal and flowing smoothly top to bottom in a laminar flow pattern without eddy patterns. Typically, the volume of chambers is carefully controlled, as the volume impacts the system time constant which is defined by: Tau=V/S, where V is effective chamber volume, and S is system pumping speed.

### SUMMARY

A plasma source is configured to produce plasma at least partially external to a plasma body, and/or in fluid communication with an interior of a vacuum chamber.

The various embodiments of the inverted plasma source disclosed in the present application aim to cure the above-mentioned drawbacks, and proposes solutions so that the inverted toroidal plasma source can be integrated into a semiconductor etch or deposition chamber, ideally without impacting the chamber volume, without disrupting axial flow patterns from the top to bottom of the chamber, without introducing turbulence, or introducing non axis-symmetric flow patterns. Further, the inverted plasma source of the present application provides solutions for maintaining the stability of the plasma and plasma location, particularly for a plasma with NF₃ chemistry.

In one embodiment, the present application discloses a novel inverted toroidal plasma source is proposed, along with novel configurations for its components. The proposed toroidal plasma source is improved as far as its lower chamber cleaning, its foreline cleaning, its oxygen radical cleaning applications, fluorine radical cleaning applications, and its point of use cleaning.

In accordance with an embodiment of the invention, a form factor is proposed, that enables reduced disruption to the vessel wall surface.

According to an aspect of the disclosure, a plasma source includes: a plasma source body, wherein the plasma source body includes a dielectric material; a ferrite core within the plasma source body; an electrode within the plasma source body; wherein the plasma source body is configured to generate a plasma when the ferrite core is energized, with the plasma generated forming at least partially external to the plasma source body, around the ferrite core, the electrode, and the dielectric material; and a mount mechanically coupled to plasma source body, for coupling the plasma source body to a vacuum vessel with the plasma source body in fluid communication with an interior of the vacuum vessel.

According to an embodiment of any paragraph(s) of this summary, wherein the plasma forms at a plasma location when the ferrite core is energized.

According to an embodiment of any paragraph(s) of this summary, at least 25% of a length of the plasma is external to the plasma source body.

According to an embodiment of any paragraph(s) of this summary, at least 50% of a length of the plasma is external to the plasma source body.

According to an embodiment of any paragraph(s) of this summary, at least 75% of a length of the plasma is external to the plasma source body.

According to an embodiment of any paragraph(s) of this summary, the plasma source body defines an inner bore; and the plasma location passes through the inner bore.

According to an embodiment of any paragraph(s) of this summary, the inner bore is part of a through-hole that also passes through the ferrite core, the electrode, and the dielectric material.

According to an embodiment of any paragraph(s) of this summary, the ferrite core is toroidal.

According to an embodiment of any paragraph(s) of this summary, the electrode is a capacitively coupled plasma (CCP) electrode.

According to an embodiment of any paragraph(s) of this summary, the CCP electrode includes copper.

According to an embodiment of any paragraph(s) of this summary, the electrode is mounted on the dielectric material.

According to an embodiment of any paragraph(s) of this summary, the dielectric material is a dielectric plate.

According to an embodiment of any paragraph(s) of this summary, the dielectric material is a dielectric material ring.

According to an embodiment of any paragraph(s) of this summary, the plasma source further includes one or more windings around the ferrite core.

According to an embodiment of any paragraph(s) of this summary, the ferrite core is energized by energizing the one or more windings.

According to an embodiment of any paragraph(s) of this summary, the plasma source further includes a cooling structure.

According to an embodiment of any paragraph(s) of this summary,

wherein the cooling structure is a cooling pipe.

According to an embodiment of any paragraph(s) of this summary, the cooling pipe contains a flowing cooling fluid that removes heat from the wall plasma source.

According to an embodiment of any paragraph(s) of this summary, the mount includes a flange.

According to an embodiment of any paragraph(s) of this summary, the flange is configured for flush mounting of the plasma source on a vessel wall.

According to an embodiment of any paragraph(s) of this summary, the mount includes a re-entrant adapter configured to pass through a port in a wall of the vacuum vessel.

According to an embodiment of any paragraph(s) of this summary, the mount further includes: a first O-ring that seals between a flange of the re-entrant adapter and the port; and a second O-ring that seals between an end of the re-entrant adapter and the plasma source body.

According to an embodiment of any paragraph(s) of this summary, the plasma source further includes a gas fitting coupled to the flange, for passing gas through the plasma into fluid communication with the interior of the vacuum vessel.

According to an embodiment of any paragraph(s) of this summary, the plasma source further includes a shower plate between the gas fitting and the plasma location.

According to an embodiment of any paragraph(s) of this summary, the plasma source body includes a reduced-thickness region that defines the plasma location at a shortest-loop location.

According to an embodiment of any paragraph(s) of this summary, the reduced-thickness region includes an indent at a perimeter of the plasma source body.

According to an embodiment of any paragraph(s) of this summary, the indent is a full scallop of variable radius.

According to an embodiment of any paragraph(s) of this summary, the indent includes a triangular cut.

According to an embodiment of any paragraph(s) of this summary, the indent includes a flat indented portion.

According to an embodiment of any paragraph(s) of this summary, the indent includes a square cut.

According to an embodiment of any paragraph(s) of this summary, the plasma source includes a gas feed to direct gas to the plasma location.

According to an embodiment of any paragraph(s) of this summary, the gas feed includes gas channels in the plasma source body.

According to an embodiment of any paragraph(s) of this summary, the gas channels direct the gas feed radially inward to an inner bore defined by the plasma source body.

According to an embodiment of any paragraph(s) of this summary, the gas channels are circumferentially spaced around the inner bore.

According to an embodiment of any paragraph(s) of this summary, a surface of the plasma source is configured to be co-planar with an inner surface of the vacuum vessel.

According to an embodiment of any paragraph(s) of this summary, the plasma source is in combination with the vacuum vessel.

According to an embodiment of any paragraph(s) of this summary, the plasma source is in combination with the vacuum vessel, with a surface of the plasma source co-planar with an inner surface of the vacuum vessel.

According to an embodiment of any paragraph(s) of this summary, the plasma location is at least partially in the interior of the vacuum vessel.

According to an embodiment of any paragraph(s) of this summary, the mount is directly mechanically coupled to the vacuum vessel.

According to an embodiment of any paragraph(s) of this summary, the mount is directly mechanically coupled to a pumping line connected to the vacuum vessel.

According to an embodiment of any paragraph(s) of this summary, the plasma source is further in combination with one or more additional plasma sources in fluid communication with the interior of the vacuum vessel.

According to an embodiment of any paragraph(s) of this summary, the one or more additional plasma sources are at least partially in the vacuum vessel.

According to an embodiment of any paragraph(s) of this summary, the plasma location is in a direct line of sight to an interior surface of the vacuum chamber.

According to an embodiment of any paragraph(s) of this summary, the vacuum vessel includes an etch chamber in which etching occurs.

According to an embodiment of any paragraph(s) of this summary, the vacuum vessel includes a deposition chamber in which deposition occurs.

According to another aspect of the disclosure, a plasma source includes: a plasma source body, wherein the plasma source body includes a dielectric material; a ferrite core within the plasma source body; an electrode within the plasma source body; wherein the plasma source body is configured to generate a plasma at a plasma location when the ferrite core is energized, with the plasma generated forming at least partially external to the plasma source body, around the ferrite core, the electrode, and the dielectric material; and wherein the plasma source body includes a reduced-thickness region that defines the plasma location at a shortest-loop location.

According to still another aspect, a method of cleaning an interior surface of a vacuum vessel, the method including: placing a plasma source as described in any other paragraph(s) of this summary in fluid communication with an interior of the vacuum vessel; energizing cleaning gas by passing the cleaning gas through a plasma created by the plasma source to produce energized cleaning gas; and thereafter cleaning the interior surface of the vacuum vessel with the energized cleaning gas.

According to still another aspect of the disclosure, a method of cleaning an interior surface of a vacuum chamber, the method including: placing a plasma source as described in claim 1 in fluid communication with an interior of the vacuum chamber; energizing cleaning gas by passing the cleaning gas through a plasma created by the plasma source to produce energized cleaning gas; and thereafter cleaning the interior surface of the vacuum chamber with the energized cleaning gas.

According to an embodiment of any paragraph(s) of this summary, the placing the plasma source includes placing the plasma source in a line of sight to the interior surface.

While a number of features are described herein with respect to embodiments of the disclosure, features described with respect to a given embodiment also may be employed in connection with other embodiments. The following description and the annexed drawings set forth certain illustrative embodiments of the disclosure. These embodiments are indicative, however, of but a few of the various ways in which the principles of the disclosure may be employed. Other objects, advantages, and novel features according to aspects of the disclosure will become apparent from the following detailed description when considered in conjunction with the drawings.

### BRIEF DESCRIPTION OF THE DRAWINGS

The annexed drawings, which are not necessarily to scale, show various aspects of the disclosure.

FIG. 1A is an oblique view of a plasma source, according to an embodiment of the disclosure.

FIG. 1B is another oblique view of the plasma source of FIG. 1A.

FIG. 1C is a cutaway view of the plasma source of FIG. 1A.

FIG. 1D is a side sectional view of the plasma source of FIG. 1A.

FIG. 1E is another sectional view of the plasma source of FIG. 1A.

FIG. 1F is another cutaway view of the plasma source of FIG. 1A.

FIG. 1G is an exploded of the plasma source of FIG. 1A.

FIG. 1H is an oblique view of a plasma source, according to another embodiment.

FIG. 1I is another oblique view of the plasma source of FIG. 1H.

FIG. 1J is a cutaway view of the plasma source of FIG. 1H.

FIG. 1K is a side sectional view of the plasma source of FIG. 1H.

FIG. 1L is another sectional view of the plasma source of FIG. 1H.

FIG. 2A is a plan view showing an embodiment with a first indent shape.

FIG. 2B is a plan view showing an embodiment with a second indent shape.

FIG. 2C is a plan view showing an embodiment with a third indent

shape.

FIG. 2D is a plan view showing an embodiment with a fourth indent shape.

FIG. 3 is an oblique view of a plasma source according to yet another embodiment.

FIG. 4 is a cutaway view of a plasma source installed into a pipe, according to an embodiment.

FIG. 5A is an exploded view of a plasma source, according to still another embodiment.

FIG. 5B is an oblique cutaway view of the plasma source of FIG. 5A.

FIG. 6A is an oblique view of a plasma source according to a further embodiment.

FIG. 6B is a magnified view of a bore of the plasma source of FIG. 6A.

FIG. 7A is an oblique view of an embodiment of a plasma source with a dielectric ring.

FIG. 7B is an oblique view of another embodiment of a plasma source with a dielectric ring.

FIG. 8 is a high-level flow chart of a method of cleaning a surface of a vacuum vessel, using a plasma source.

FIG. 9 is a schematic view of an installation using plasma sources.

FIG. 10 is another schematic view of an installation using plasma sources.

### DETAILED DESCRIPTION

A plasma source may be configured to be in fluid communication with the interior of a vacuum chamber, such as by being installed in a wall of a vacuum vessel that encloses the chamber, or in a pipe that is connected to the chamber. The plasma source may produce plasma in a line of sight of a surface to be cleaned, such as an internal surface of the vessel, which may be used for processes such as deposition or etching.

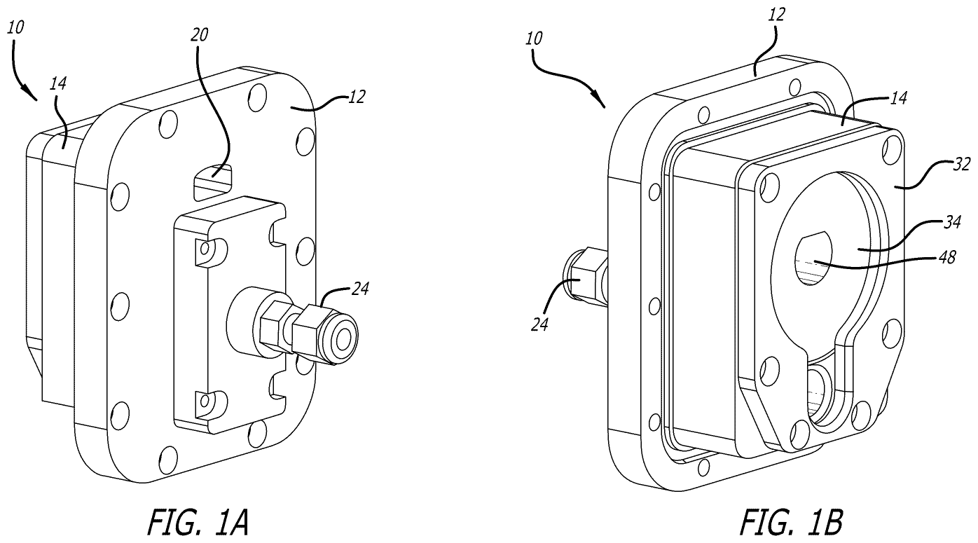

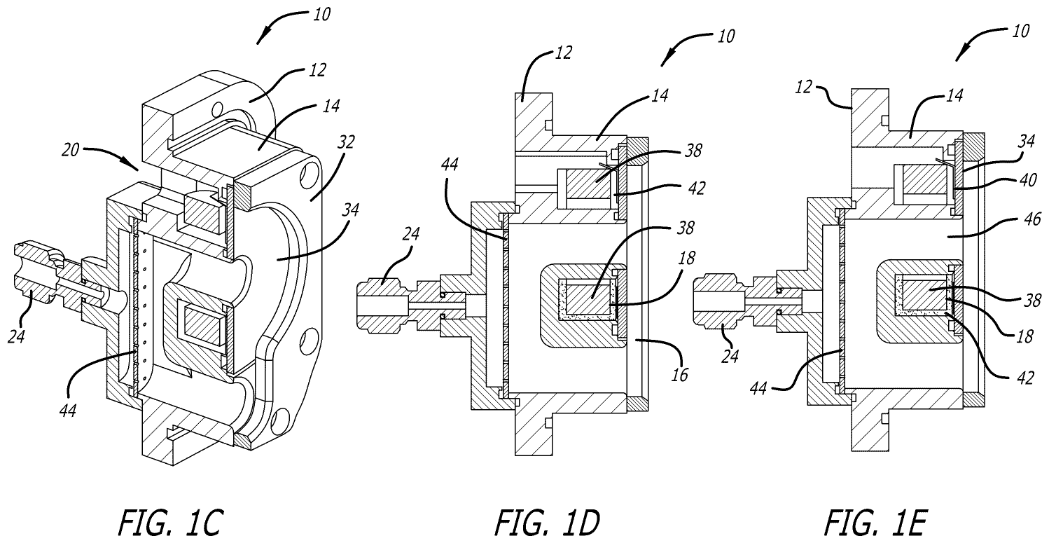

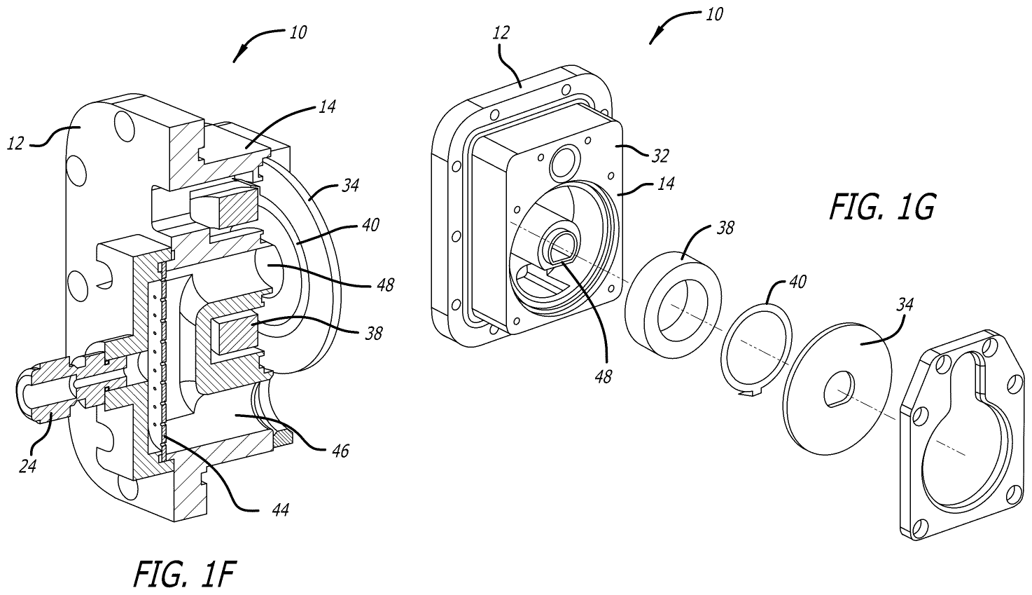

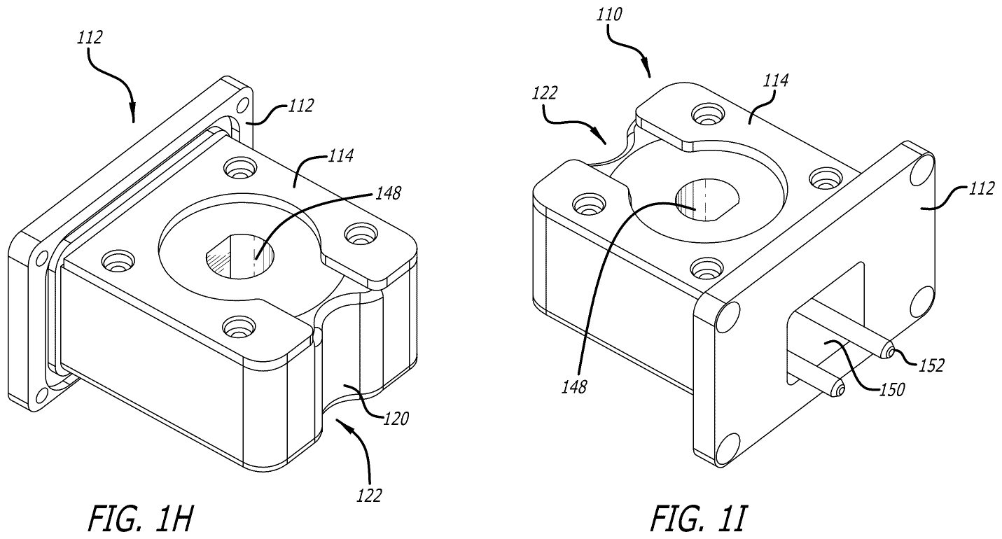

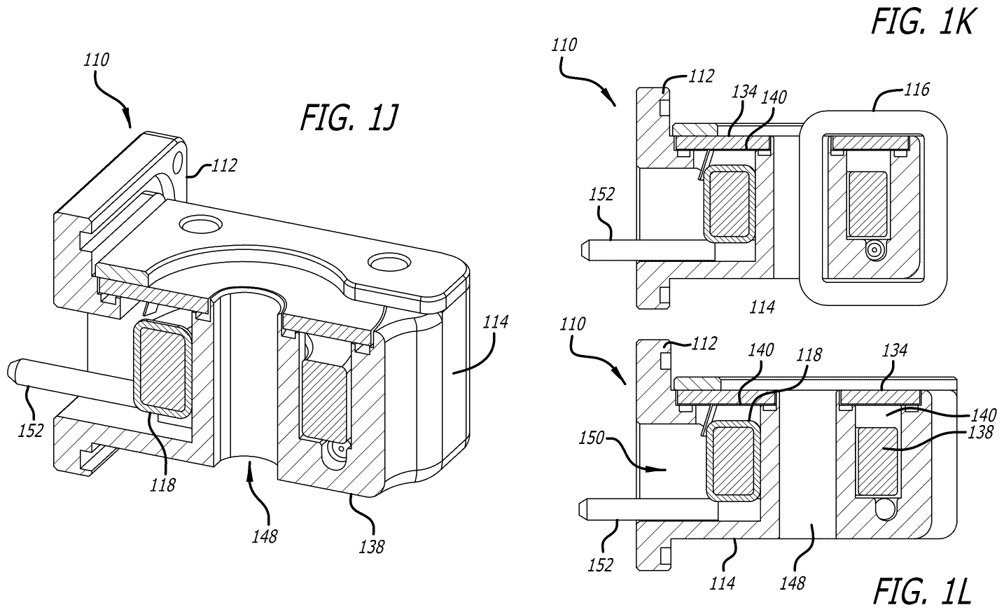

Referring initially to FIGS. 1A-1G, a plasma source 10 is shown. FIGS. 1A and 1B illustrate lateral views of the plasma source 10. FIGS. 1C, 1D, and 1E illustrate further lateral views of the plasma source 10.

In a specific (non-limiting) embodiment, FIGS. 1A and 1B show an

embodiment of the wall source 10 with a flange mount 12 coupled to a plasma source body 14, for example including a toroid such as that sold as EPCOS-TDK #B64290L0022X087, having toroid material: N87, a cross sectional area of 95.75 mm², with a toroidal plasma path length of approximately 124.62 mm, a gas distribution of orifice plate or baffle, and a dielectric of alumina cover plate. Many other dimensions and arrangements are possible.

The plasma source 10 includes a toroidal plasma source, which exhibits an inverted geometry, although those skilled in the art will appreciate that the plasma source 10 may have any of a variety of suitable shapes. As it will be described in detail in the following portions of this document, the plasma source 10 includes the at least one plasma source body or vessel 14 configured to generate at least one plasma 16 (See FIG. 1D). At least one primary winding 18 may be used to provide energy to at least one component within the plasma source body 14 (See FIG. 1D). Further, in the illustrated embodiment, the plasma source 10 may include at least one thermal management inlet/outlet 20 (hereinafter inlet) configured to permit active thermal management of the plasma source 10 during use. As such, the thermal management inlet 20 may be in fluid communication with at least one fluid source.

FIG. 1A shows the exterior surface of the wall source 10, with a gas fitting 24 mounted on the flange 12. The gas fitting 24 may be used for feeding a cleaning gas to the plasma source 10. As shown in FIG. 1B, an interior surface 32 of the wall source 10 has a surface co-planar with the interior wall of the chamber or vacuum vessel (not shown in this figure). In FIG. 1C it may be observed that the interior surface 32 of the wall source 10 may adjoin a surface of a dielectric plate 34, and the interior face 32 may be co- planar with an inside wall of vessel. In FIG. 1D, a lateral view of the wall source 10, it may be observed an area (plasma location) 36 where the inductively coupled plasma 16 is present, is around the ferrite (magnetic) core 38, and a capacitively coupled plasma (CCP) electrode 40. The CCP electrode 40, which may be made of copper, may be on a back side of the dielectric plate 34, which may be made of alumina. There may be a space 42 around the ferrite core 38, which may contain a suitable potting material. FIG. 1E is a schematic side view of the wall source 10, also showing a gas distribution/shower head 44 may be observed.

When a vacuum is established on the outside of the plasma source body 14, the primary winding 18 may be energized with RF energy. At least one generated plasma 16 forms at least partially on the exterior of the plasma source 10, forming poloidal current loops around the minor diameter of the torus, on the outside of the vessel or plasma source body 14. The current loops may overlap in the center of the torus.

In the illustrated embodiment the plasma 16 is partially on the outside of the plasma source body 14, though most of the plasma 16 follows a channel 46 that is inside of the external surface of the plasma source body 14. The channel 46 includes a bore 48 that passes through the plasma source body 14, through the dielectric plate 34, through the ferrite core 38, and through the electrode 40. Less than half of a length of the plasma 16 may be outside of the plasma source body 14. For example, at least 25% of the length of the plasma 16 may be outside of the plasma source body 14. In other embodiments, some of which are described below, a majority of the length of a plasma (for example at least 50% or at least 75% of the length of the plasma source body) may be external to a plasma source body.

The illustrated implementation for the wall source 10 may be installed into the wall of a chamber (or otherwise in fluid communication with the chamber). In some applications it may be desirable to have one or more plasma sources located in a “point of use” arrangement in the chamber walls which may permit a direct line of sight from the plasma to the surface being cleaned, which results in minimal recombination losses, and high utilization of the generated reactive radicals. In another embodiment, the one or more plasma sources need not be located in a “point of use” arrangement in the chamber walls so as not to disrupt the normal operation of the chamber. This applies to both etch and deposition chambers. For example, when integrating a local, point of use plasma source, a generally axisymmetric flow pattern within the chamber from top to bottom may be maintained. Optionally, the chamber (vessel) walls and bottom may include generally flat surfaces in order to minimize turbulence or disruption of flow patterns. Optionally, the wall source 10 may be configured to resulting a minimum change to the effective chamber volume. The implementation of plasma source illustrated in FIGS. 1A to 1G addresses all these integration factors.

As stated above, part of the plasma loop is contained in a more conventional plasma block, but a part of the plasma loop extends into the chamber volume. The surfaces facing the plasma may be anodized, or coated with a dielectric material. Alternatively, the plasma block could be fabricated from a solid ceramic or dielectric material, such as aluminum oxide or aluminum nitride. A gas feed introduces gas from the outside of the chamber (vessel) through the plasma. Optionally, a gas distribution plate can be installed so that the gas is evenly distributed within the plasma to maximize dissociation efficiency. An isolation valve, such as a diaphragm isolation valve, can be placed in the gas feed line, close the plasma source, in order to define and limit the effective chamber volume.

This arrangement has a plurality of advantages. Since one part of the plasma is within the chamber, line of sight is maintained between the plasma and a surface to be cleaned. This minimizes recombination losses, particularly with a gas like oxygen that recombines very easily. However, the interior chamber (vessel) surface is nominally flat, such that flow patterns within the chamber will not be disrupted. With this source installed on a chamber the effective chamber volume is slightly increased, but only to a small extent by the volume of the enclosed portion of the plasma block. In this implementation the dielectric break of the plasma block is implemented with a flat dielectric plate that is clamped by a retaining structure. The O-rings are shielded from direct exposure or line of light to the plasma, being located in a groove on an inner surface of the flange 12.

What follows now are different embodiments and applications of a variety of plasma sources. Common details and features may be omitted in some of the following embodiments, and it should be understood that features from various of the embodiments may be combined where appropriate in a single device.

FIGS. 1H to 1L illustrate some possible configurations of a mini wall source, a plasma source 110 including elements discussed above, and exemplarily characterized in a specific (non-limiting example) embodiment by having a flange mount 112, with a toroidal ferrite magnetic core 138: for example EPCOS-TDK #B64290L0048X087, the toroid Material: N87, cross sectional area: 82.60 mm², the toroidal plasma path length of approximately 110.97 mm, and a dielectric of alumina cover plate 134. The wall source 110 also includes an electrode 140; a space 142 around the magnetic core 138, such as for receiving a potting material; a winding 118 around the core 138; and a channel 150 for receiving a cooling tube 152, for example for using flowing water to remove heat from the wall source 110. A bore 148 is defined by a plasma source body 114.

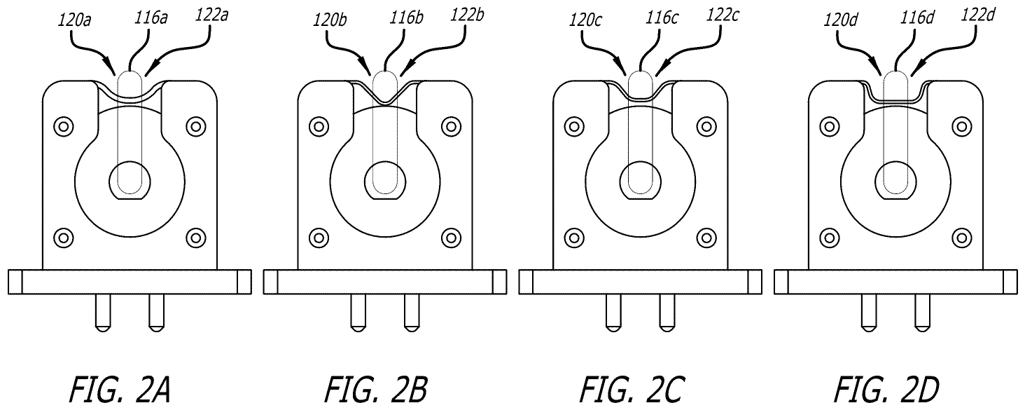

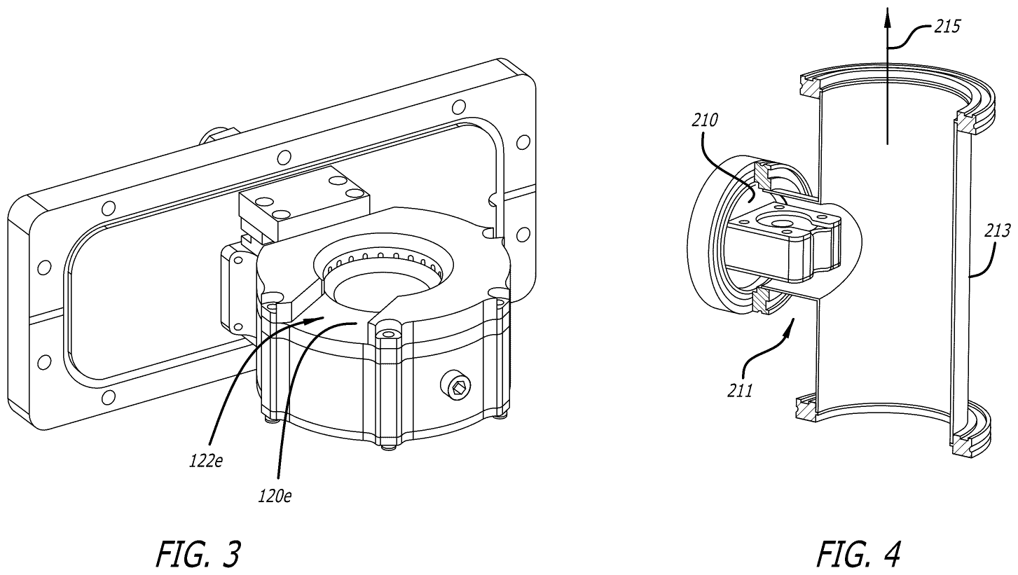

The plasma source body 114 has a thinned region 120 defines a plasma location 122 at a shortest-loop location through the bore 148 that is through the plasma source body 114. The thinned region 120 may aid in anchoring the plasma at a defined location 122, preventing undesirable movement of the plasma (and possible change in performance) as the plasma source 110 is operated. The thinned region 120 may include an indent at a perimeter of the plasma source body 114. Example shapes of the indent are described below, where FIGS. 2A-2D illustrate several versions of mini wall sources, with the figures illustrating several non-limiting options for the geometry of the plasma body. FIG. 3 illustrates a plasma body with a reduced thickness in one region.

Specifically, FIG. 2A illustrates a geometry with an indent 120a having a full scallop of variable radii, while in this figure the representative plasma loop 116A may also be observed at a plasma location 122A. FIG. 2B illustrates an indent 120b having a geometry with triangular cut, with straight wall and variable radii, defining a plasma location 122B where a plasma 116B is preferentially located. FIG. 2C illustrates an indent 120c having a geometry with flat edge, with tapered walls and with variable radii, defining a plasma location 122C. FIG. 2D illustrates an indent 120d having a geometry with square cut and variable radii, defining a plasma location 122D. FIG. 3 illustrates a geometry with a thinned region 120e of reduced thickness to define a plasma location 122e.

The inductively coupled plasma forms where its loop can form the shortest path. This requires the least voltage and energy. Because NF₃ is an electronegative gas, an NF₃ plasma tends to be collapsed into a narrow current channel. Particularly with an NF₃ or another electronegative plasma, if the plasma loop can form with equivalent length in many places, the plasma will have an opportunity to shift locations easily and have an unstable location. For example, the plasma location can shift easily with minor disturbances, such as flow turbulence. An unstable plasma position is undesirable. Instabilities may lead to reduced operation regime due to plasma extinguishing, an unstable load to the RF power supply, or reduced dissociation performance.

In order to stabilize the plasma location, the geometry of the body of the plasma source can be formed such that the plasma loop is shortest at one defined location. This will stabilize the location of the plasma loop. There are several options for the geometry of the plasma body, as discussed above and as shown in FIGS. 2A to 2D. The shortest loop path can be defined by a scallop, V groove, or a flat edge. Alternatively, the thickness of the plasma body can be reduced in one region to form a shorter loop path, as shown in FIG. 3.

In some applications it is desirable to have a plasma source in a pumping line, or foreline, in order to remove byproduct from the pumping line. In this application the gas source can either be gas that is flowing through the system and chamber, or an additional gas feed can be provided for the foreline plasma source. It is often desirable that the foreline plasma source does not restrict the pipe diameter or pumping speed in any way. To satisfy this constraint, the inverted toroidal plasma source 210 can be mounted in a tee fitting 211, adjacent to the main foreline pipe 213, as shown in FIG. 4. FIG. 4 indicates the primary flow path 215 through pumping line 213. It is desirable that the foreline plasma source does not restrict the pipe diameter or pumping speed in any way.

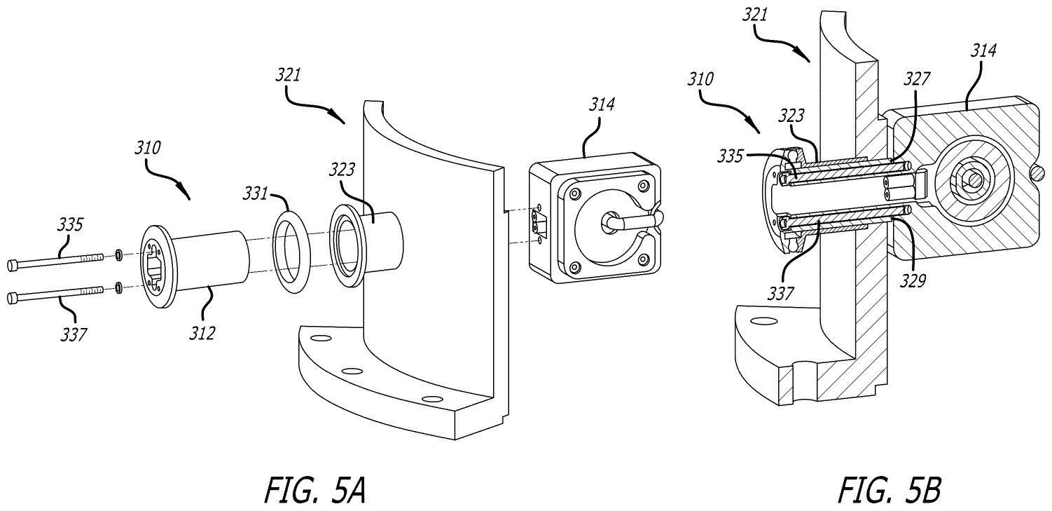

FIGS. 5A and 5B show a wall plasma source 310 that includes a small flange (KF) fitting adapter 312. In some applications it is desirable to mount the plasma source into a vessel 321 using an existing port 323 on the vessel 321. A common port on vessels is the standard KF-style, or CONFLAT port. For these applications, a wall plasma source 310 is configured such that the re-entrant adapter 312 can be inserted through the port 323. Vacuum seals 327 and 329 are parts of the plasma source 310, between an end of the adapter 312 and a plasma source body 314. Another seal 331 is made between a flange 333 of the adapter 312, and the port 323 on the vessel 321. This allows all the interfaces to the plasma source 310, such as water services, electrical connections, and mechanical securing bolts 335 and 337, to remain at atmosphere, while the vacuum integrity of the vacuum vessel is maintained with conventional O-ring seals. This arrangement enables the integration of a point of use plasma source with an existing chamber with minimal modifications of the vacuum vessel, as shown in FIGS. 5A and 5B. FIG. 5A shows in an exploded view, and FIG. 5B shows in an assembly view an implementation using an existing port in the side of a vessel. However, this method could also be used to mount the plasma source through a port in the bottom plate, or top of a vessel. Specifically, FIG. 5A illustrates an arrangement that comprises, in the illustrated order at least the re-entrant adapter 312, the existing KF port 323, the existing vessel wall 321, a plasma source, including the plasma source body 314 and the components therein (similar to those described with regard to other embodiments). A plasma approximation representation 316 at a plasma location 336 is also shown. FIG. 5B illustrates in an assembly view at least the above enumerated elements, while an access for interfaces and the location of the O-rings are as well evidenced.

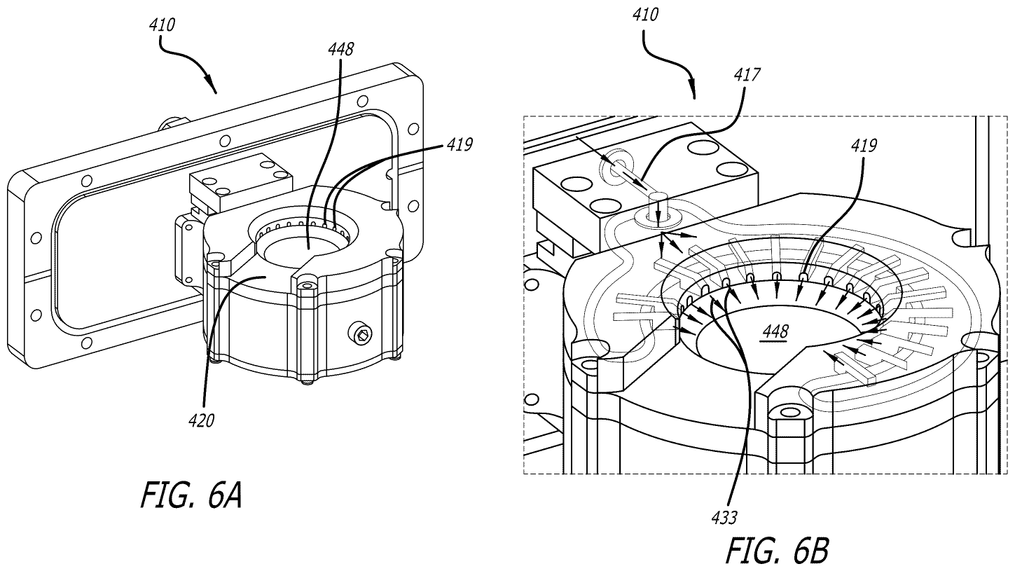

In another embodiment, in a wall plasma source 410 illustrated in FIGS. 6A and 6B, gas feed is provided into a bore 448, providing associated advantages are discussed. In some applications, it is desirable to have the plasma source dissociate gas that is already flowing through the chamber. In some applications, it is desirable to have a dedicated gas feed for the plasma source. This minimizes the gas use, while maximizing the dissociation efficiency and radical output of the plasma source. In order to achieve these goals, it is helpful to have a gas feed to direct the feedstock gas into the region of highest plasma density, which is the central bore. FIG. 6A shows the wall plasma source 410 where a gas ring is formed, that directs gas from an external source, through an entry channel/fitting 417, to a series of small channels 419 leading to the inner bore 448. In this figure, a region of reduced thickness 420 to define plasma location may be observed.

With this arrangement the incoming feedstock gas has a high probability of interacting with the plasma, and therefore increasing dissociation efficiency. The gas channels 419 can be arranged perpendicular to the bore, as may be seen in FIG. 6B, or at a slight angle to create a swirling, or rotational gas path, which will further increase the residence time and probability of the gas interacting with the high-density plasma region. The gas may be inserted at the bore of the source. In FIG. 6B, the gas distribution is evidenced with by arrows 433.

The use of the gas channels illustrated in the wall plasma source 410 may be applied to other types of plasma sources. For example, small gas channels outletting into a bore may be a part of a plasma source that is not wall mounted.

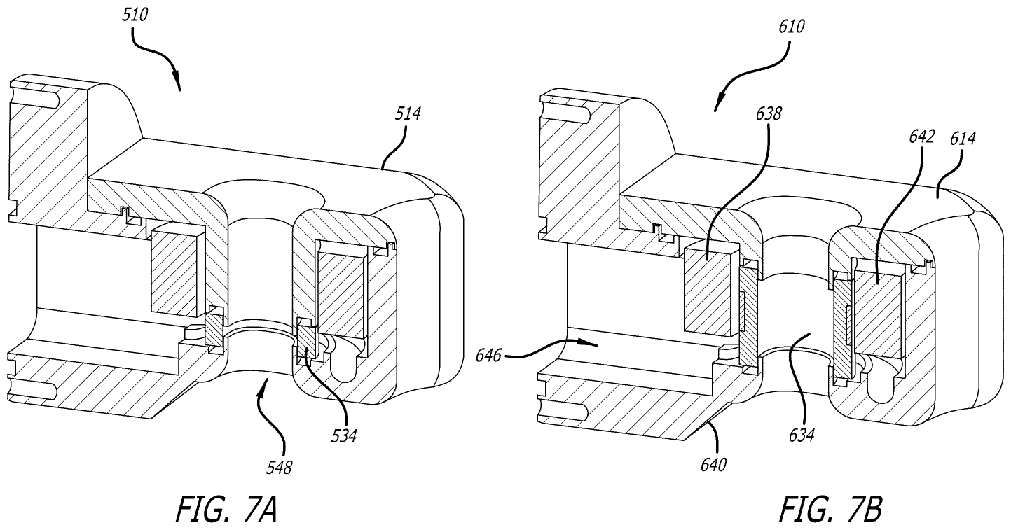

FIGS. 7A and 7B illustrate respective plasma sources 510 and 610 with alternate dielectric locations. As evident from FIG. 7A, the plasma source 510 has an aluminum (or other suitable electrically-conductive material) body 514, and a configuration with a short dielectric 534, located around part of a central bore 548 defined by the body 514.

FIG. 7B illustrates a configuration of the plasma source 610 with an aluminum (or other suitable electrically-conductive material) body 614, and a long dielectric 634. A cavity 642 for potting materials and a channel 646 for cooling (a tube) are also evident, around a magnetic core 638 (and associate winding(s)). Corresponding features elements are also present in the configuration illustrated in FIG. 7A. In addition, in the configuration of FIG. 7B it is evident the placement of the CCP ignition electrode 640, along an outer surface of the dielectric tube 634.

Specifically, an alternative construction for the plasma source is to fabricate the top and bottom structure of the body with a metal such as aluminum, and form the dielectric break with a short section of tube that forms the inner bore. The aluminum sections may be anodized, or coated with a dielectric material. The dielectric tube material can be aluminum oxide, or aluminum nitride or similar material. The dielectric break will be cooled by means of being in contact with potting material that fills the inner cavity. A water cooling tube in this cavity can remove the heat from the structure. O-rings on the ends of the ceramic tube provide a seal to the aluminum body components. A metallic electrode can be bonded, adhered, or deposited on to the surface of the dielectric tube on the atmosphere side, to form a buried electrode to serve as a barrier discharge or capacitively coupled plasma for ignition purposes.

The above highlighted configurations and their advantages find applicability at least in connection with lower chamber cleaning, foreline cleaning, fluorine radical cleaning, oxygen radical cleaning applications, and point of use cleaning.

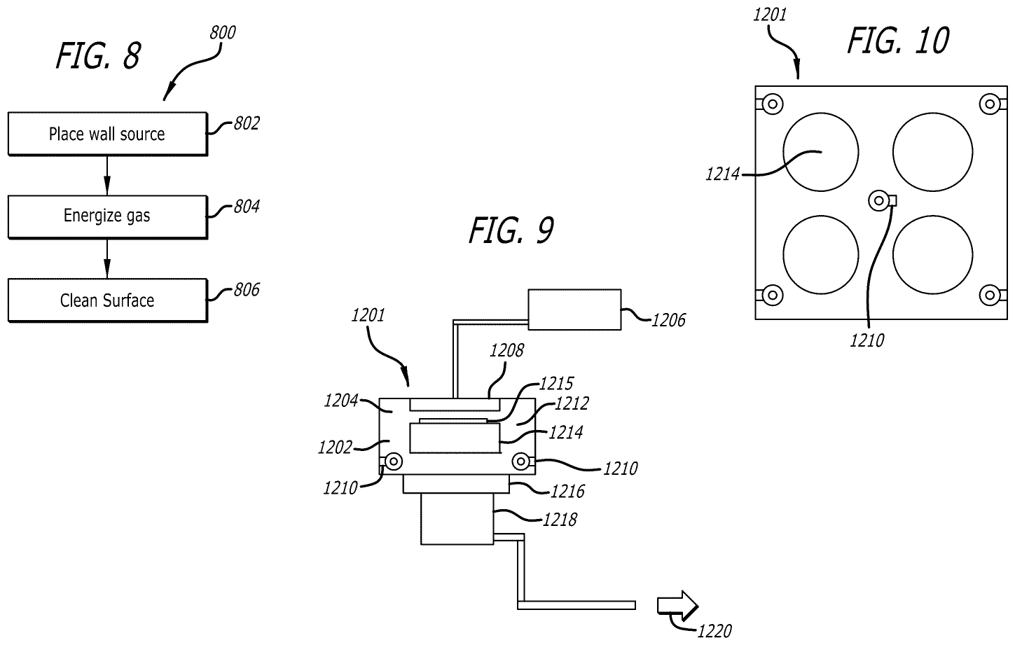

FIG. 8 shows a high-level flow chart 800 of cleaning an interior surface of a vacuum vessel using one or plasma sources, such as any of the wall sources described above. In step 802 the plasma source(s) are placed in fluid communication with an interior of a vacuum vessel. In step 804 cleaning gas is energized by passing the cleaning gas through a plasma created by the plasma source to produce energized cleaning gas. In step 806, the interior surface of the vacuum vessel with the energized cleaning gas.

An application of the above-described plasma sources may be found in the placement of plasma source(s) in a small, compact environment, such as hard to clean regions of a semiconductor-processing chamber 1201 shown in FIG. 9. This illustrative chamber 1201 consists of a gas box 1206, a showerhead 1208, an upper chamber region 1206, a wafer pedestal 1214, a wafer 1215, a pressure control valve 1216, and a pump 1218. A plasma source is placed upstream above the showerhead 1208. The placement of one or more wall plasma sources 1210, such as those described in any of the embodiments above, can be in the lower chamber 1202, above the pressure control valve 1216 and below the pedestal 1214. This integration of the inverted toroidal plasma source with a semiconductor processing chamber enables radicals to be generated in the bottom of the chamber while minimizing transport loss or recombination losses between the plasma and the surfaces in the bottom of the chamber vessel to be cleaned. This can also be achieved with multiple plasma sources 1210 in the chamber 1201, as illustrated in FIG. 10. Therein there are multiple plasma sources in a large multi-wafer chamber, for example a quad wafer chamber.

Although the disclosure has been shown and described with respect to a certain embodiment or embodiments, equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the disclosure. In addition, while a particular feature of the disclosure may have been described above with respect to only one or more of several illustrated embodiments, such feature may be combined with one or more other features of the other embodiments, as may be desired and advantageous for any given or particular application.

What is claimed is:

1. A plasma source comprising:
a plasma source body, wherein the plasma source body includes a dielectric material;
a ferrite core within the plasma source body;
an electrode within the plasma source body;
wherein the plasma source body is configured to generate a plasma when the ferrite core is energized, with the plasma generated forming at least partially external to the plasma source body, around the ferrite core, the electrode, and the dielectric material; and
a mount mechanically coupled to plasma source body, for coupling the plasma source body to a vacuum vessel with the plasma source body in fluid communication with an interior of the vacuum vessel.

2. The plasma source of claim 1, wherein at least 50% of a length of the plasma is external to the plasma source body.

3. The plasma source of claim 1,
wherein the plasma source body defines an inner bore; and
wherein a plasma location, where the plasma forms when the ferrite core is energized, passes through the inner bore.

4. The plasma source of claim 3, wherein the inner bore is part of a through-hole that also passes through the ferrite core, the electrode, and the dielectric material.

5. The plasma source of claim 1, wherein the ferrite core is toroidal.

6. The plasma source of claim 1, wherein the electrode is a capacitively coupled plasma (CCP) electrode.

7. The plasma source of claim 1, wherein the electrode is mounted on the dielectric material.

8. The plasma source of claim 1, wherein the dielectric material is a dielectric plate.

9. The plasma source of claim 1, wherein the dielectric material is a dielectric material ring.

10. The plasma source of claim 1, further comprising one or more windings around the ferrite core.

11. The plasma source of claim 1, wherein the mount includes a flange.

12. The plasma source of claim 1, wherein the mount includes a re-entrant adapter configured to pass through a port in a wall of the vacuum vessel.

13. The plasma source of claim 1, further comprising a gas fitting coupled to the flange, for passing gas through the plasma into fluid communication with the interior of the vacuum vessel.

14. The plasma source of claim 1, wherein the plasma source includes a gas feed to direct gas to a plasma location, where the plasma forms when the ferrite core is energized.

15. The plasma source of claim 14, wherein the gas feed includes gas channels in the plasma source body.

16. The plasma source of claim 15, wherein the gas channels direct the gas feed radially inward to an inner bore defined by the plasma source body.

17. The plasma source of claim 1, in combination with the vacuum vessel.

18. A plasma source comprising:
a plasma source body, wherein the plasma source body includes a dielectric material;
a ferrite core within the plasma source body;
an electrode within the plasma source body;
wherein the plasma source body is configured to generate a plasma at a plasma location when the ferrite core is energized, with the plasma generated forming at least partially external to the plasma source body, around the ferrite core, the electrode, and the dielectric material; and
wherein the plasma source body includes a reduced-thickness region that defines the plasma location at a shortest-loop location.

19. A plasma source comprising:
a plasma source body, wherein the plasma source body includes a dielectric material;
a ferrite core within the plasma source body;
an electrode within the plasma source body;
wherein the plasma source body is configured to generate a plasma at a plasma location when the ferrite core is energized, with the plasma generated forming at least partially external to the plasma source body, around the ferrite core, the electrode, and the dielectric material;
wherein the plasma source body defines an inner bore;
wherein the plasma location passes through the inner bore;
wherein the plasma source includes a gas feed to direct gas to the plasma location; and
wherein the gas feed includes gas channels that direct the gas feed radially inward to an inner bore defined by the plasma source body.

20. A method of cleaning an interior surface of a vacuum chamber, the method comprising:
placing a plasma source as described in claim 1 in fluid communication with an interior of the vacuum chamber;
energizing cleaning gas by passing the cleaning gas through a plasma created by the plasma source to produce energized cleaning gas; and
thereafter cleaning the interior surface of the vacuum chamber with the energized cleaning gas.
